(19) United States
(12) Patent Application Publication
(10) Pub. No.: US 2007/0279877 A1
(43) Pub. Date: Dec. 6, 2007

(54) Circuit board arrangement

(76) Inventors: Stephan Dobritz, Dresden (DE); Jesus Mennen Belonio, Dresden (DE); Ingolf Rau, Munich (DE); Axel Sachse, Dresden (DE)

Correspondence Address: SLATER & MATSIL LLP, 17950 PRESTON ROAD, SUITE 1000, DALLAS, TX, 75252, US

(21) Appl. No.: 11/443,494

(22) Filed: May 30, 2006

(51) Int. Cl. H05K 7/00

(52) U.S. Cl. 361/760; 174/260

(57) ABSTRACT

A circuit board arrangement having a circuit board with a contact strip formed on a side edge and with at least one electronic component, electrically connected to the circuit board, on each of the component sides, the outer contour of the circuit board arrangement being formed by an encapsulating case molded in one piece onto the circuit board and essentially enclosing the circuit board, and the contact strip protruding from the encapsulating case.

### TECHNICAL FIELD

The present invention relates to a circuit board arrangement.

### BACKGROUND

Circuit boards, also called board or printed circuit, are used for mounting and connecting electronic components without the use of conventional wires by producing the connection from one or more conductive layers that are located on an insulating material. Such circuit boards can be used for producing different modular components, the function of which is determined by the electronic components mounted on the circuit board.

Circuit boards, which are intended to be suitable as extension components for electronic devices such as, for example, PCs, printers, servers, etc., to be plugged, for example, into a slot provided on the main board, for example, exhibit a contact strip on one of their side edges.

To meet the continuously increasing demands on performance of such circuit board arrangements or modules, the circuit boards are assembled double-sidedly with electronic components with high packaging density which are electrically conductively connected to the circuit board by means of solder balls (solder bumps) or other suitable electronic connecting elements. Due to the compulsion to increase packaging density, for example, the use of wafer level packages (WLPs) becomes more and more important. It is conventional, however, that, especially when WLPs are used, additional mechanical protection becomes necessary. This is normally done, for example, by using the WLPs in cased form.

Since the circuit board arrangements are bound to standardized specifications with regard to their size/dimension, an increase in performance can still be achieved, for example, by increasing the packaging density and improving the electronic components.

The demands on the system design set in conjunction with production of such circuit board arrangements, e.g., with regard of optimization of handling, thermal characteristics, ruggedness, aesthetics, electrical properties, reliability, are becoming more and more difficult. By way of example, a high insertion density with active and passive electronic components represents a large risk factor in the context with mechanical handling during the processing and testing.

It has hitherto been attempted to meet the different requirements by a suitable combination of measures such as, for example, the improvement of the soldering methods, by optimized design rules and geometries, a shape of the circuit board adapted to the assembly. For example, standardized arrangements of the circuit board for the electrical/mechanical contacting, external dimensions, introduction of protected zones on the circuit board can be mentioned.

### SUMMARY OF THE INVENTION

According to one embodiment of the invention, a circuit board arrangement is provided, comprising a circuit board with a contact strip formed on a side edge and with at least one electronic component, electrically connected to the circuit board, on each of the component sides, the outer contour of the circuit board arrangement being formed by an encapsulating case molded in one piece onto the circuit board and essentially enclosing the circuit board, and the contact strip protruding from the encapsulating case.

These and other features of the invention will be better understood when taken in view of the following drawings and a detailed description.

### BRIEF DESCRIPTION OF THE DRAWINGS

Exemplary embodiments of the invention are shown in the attached drawing and will be explained in greater detail in the text that follows. In the drawing, identical components are provided with identical reference symbols.

FIGS. 1a to 1d in each case show a diagrammatic representation of a circuit board arrangement according to in each case one embodiment of the invention in cross section;

FIG. 2a shows a diagrammatic representation of a circuit board before the encapsulating case is molded on, according to an embodiment;

FIG. 2b shows a diagrammatic representation of a circuit board arrangement with a circuit board according to FIG. 2a;

FIG. 3a shows a diagrammatic representation of a circuit board before the encapsulating case is molded on, according to another embodiment;

FIG. 3b shows a diagrammatic representation of a circuit board arrangement with a circuit board according to FIG. 3a;

FIG. 4 shows a diagrammatic representation of a circuit board arrangement according to a further embodiment of the invention in a top view; and

FIG. 5 shows a diagrammatic representation of a circuit board arrangement according to a further embodiment of the invention in a top view.

### DETAILED DESCRIPTION OF ILLUSTRATIVE EMBODIMENTS

In one embodiment of the invention, a circuit board arrangement is provided, which shows high reliability and ruggedness with increasing packaging density and complexity and additional mechanical protection. The external dimensions of the circuit board arrangement are reliably adapted accurately to corresponding standards.

By molding onto the circuit board a one-piece encapsulating case in one embodiment of the invention, which encloses all electronic components mounted on both sides on the circuit board, the circuit board arrangement receives a predetermined outer contour. Since the encapsulating case can be molded on by means of a casting process by using a casting mold, the shape or outer contour of the circuit board arrangement can be determined by the cavity of the casting mold, the encapsulating case being molded onto the circuit board in such a manner that the edge exhibiting the contact strip protrudes from the encapsulating case with a predetermined section. The form of the circuit board arrangement can thus be adapted precisely to existing standards. In consequence, the encapsulating case, which can be produced by means of a single process step, can have any possible outer contour which can be produced by casting molds and which is optimally adapted to the later application, the encapsulating case forming a compound structure with the circuit board.

The contact strip which may be formed on a side edge of the circuit board and can be inserted, for example, in a slot provided on a main board of an electronic device, protrudes from the encapsulating case with a predetermined section, this predetermined section of the contact strip, that is to say the area free of the case from the free end edge of the contact strip to the adjoining outer wall of the encapsulating case, being determined before the encapsulating case is molded on and in each case corresponding to the requirements for the later use of the circuit board arrangement.

Since the component sides of the circuit board that are equipped with the electronic components are completely surrounded by the encapsulating case, the electronic components can be mounted on the circuit board with optimum insertion density. Furthermore, this circuit board arrangement provides the possibility of assembly with, for example, WLPs (wafer level packages) since the encapsulating case advantageously creates an additional mechanical protection for these and also prevents the electronic components from being impaired in their functionality by, for example, dust or soiling from the later environment of the circuit board arrangement. In addition, there is no longer a necessity for taking into consideration subsequent handling at the edge areas of the circuit board.

A further advantage of the circuit board arrangement also consists in that product codes or the like can be printed onto the outer surfaces of the encapsulating case at a freely selectable position. However, it is also possible to form further/other identifications for the circuit board arrangements such as, for example a logo of the manufacturer or the like, as far as is possible by means of casting methods, in one piece on a surface of the encapsulating case which can be formed as recessed or raised representations during the production of the encapsulating case.

According to an embodiment of the invention, the encapsulating case is molded onto the equipped circuit board by means of injection molding, leaving the contact strip exposed. During the injection molding, the contact strip is not covered with casting compound and, in consequence, casting material does not need to be removed or cleaned from it after the injection molding. That is to say, the edge area or section of the circuit board which is free of the encapsulating case and which can extend from the free end edge of the contact strip to the end edge of the contact sections formed thereon or beyond these by a predetermined amount is optimally adapted to the later application due to the corresponding previous adaptation of the casting mold relative to the circuit board.

Since the encapsulating case enclosing the completed circuit board is produced in an injection molding process, very thin wall sections can be advantageously formed which can extend on or above the at least one electronic component and along the corresponding narrow end edges of the circuit board. Since the encapsulating case is an all-cast body with a homogeneous structure of the material and has a compound structure with the circuit board, the electronic components are reliably protected by the encapsulating case against any mechanical actions of forces which could possibly occur such as impact or hit. Naturally, it is understood to be an unintended action of force and not one with the intention of destroying the circuit board.

According to a further embodiment of the invention, the at least one electronic component and the connecting elements electrically connecting the electronic components to the circuit board are completely embedded in the casting compound of the encapsulating case, wherein the at least one electronic component can be, for example, a microelectronic component. Both the electronic components and their electrical connecting elements are bound into the casting compound. In consequence, it is not necessary to mount the electronic components/connecting elements on the circuit board by means of additional underfilling material or the like. The encapsulating case is produced from a suitable casting material which can fill all intermediate spaces. For example, the casting compound is introduced into the casting mold with such pressure that all intermediate spaces are filled without damaging the electronic components/connecting elements or the circuit board itself.

According to a further embodiment of the invention, the encapsulating case is arranged to be plate-shaped in adaptation to the circuit board, the encapsulating case exhibiting in the area of the component sides of the circuit board a plane upper and a plane lower wall area, three sidewall sections connecting the upper and lower wall area and two wall sections which in each case extend from the upper and the lower wall area, respectively, to the corresponding surface of the circuit board on the contact strip side. This means that all edge sections of the circuit board excepting the contact strip are completely surrounded by casting material. If a standardized circuit board, commercially available per se, is used for producing the circuit board arrangement, the side edges of the circuit board, which are to be surrounded by a casting compound, must naturally be reduced in size by an amount before the encapsulating case is molded on so that the circuit board arrangement finally has precisely the correct dimensions when the circuit board is surrounded by encapsulating case sections at the side edges. Since, however, the shape or outer contour is determined by the cavity of the casting mold, it is not necessary for the areas to be separated from the original circuit board to have to be dimensioned with high precision since these are supplemented by casting compound, that is to say encapsulating case sections and thus the standardized shape and size specifications for a certain circuit board arrangement are met in every case. Unevennesses or roughnesses that may occur when the corresponding side edge sections of the circuit board are removed are without concern, in consequence, since any irregularity which may occur is equalized by the encapsulating case. The production method can thus be simplified, and thus be made more cost-effective, for such a circuit board arrangement.

According to an arrangement of the present embodiment, the three sidewall sections and the two wall sections have mold drafts for removing a two-part casting mold. The shape or form of the mold drafts are in each case predetermined by the casting mold or its cavity, respectively, in such a manner that after the casting mold has hardened, a part of the two-part casting mold can in each case be removed easily and without having to destroy it, perpendicularly in relation to the circuit board plane.

According to an arrangement of the embodiment, the mold draft is formed in the shape of a radius at least at the sidewall section facing away from the contact strip and/or the two wall sections on the sides of the contact strip. As an alternative, the mold drafts can also be formed by level oblique areas that, in each case, extend from a free circumferential edge of the upper wall area and/or the lower wall area of the encapsulating case in the direction of the circuit board plane.

According to an embodiment of the invention, at least one locking recess is formed in at least one of the two sidewall sections of the encapsulating case facing away from one another. This locking recess can be used, for example, for locking the circuit board arrangement into a corresponding locking receptacle of the terminal and shaped in accordance with standardized specifications. In adaptation to conventional circuit boards, such a locking recess can be formed, for example, as a continuous cross-sectionally semicircular recess in the corresponding sidewall section. For example, two or more such locking recesses can be formed in in each case both sidewall sections. The number, arrangement and shape of the locking recesses in each case depends on the later application of the circuit board arrangement and can be determined a priori by the selection of a corresponding casting mold. As an alternative, however, it is also possible to initially construct the sidewall sections of the encapsulating case to be level and to produce the locking recesses only subsequently by means of mechanical machining.

According to an embodiment of the invention, sections of the end edge of the circuit board facing away from the contact strip are arranged in one plane with the outer area of the corresponding sidewall section of the encapsulating case. In concrete terms, this means that the rear edge of the circuit board is not completely covered with casting compound but sections thereof finish flush in one plane with the corresponding free surface of the sidewall section of the encapsulating case. This can be achieved, for example, by the fact that, on the edge of the circuit board facing away from the contact strip, recesses are formed which are filled up by casting compound in the subsequent casting process, the edge sections of the rear edge of the circuit board, by which the recesses are bounded, being free of casting compound.

This can be done, for example, by molding leaving these edge sections free (exposed molding) or, for example, by initially surrounding or covering these rear edge sections completely with casting compound by forming the corresponding sidewall section during the molding, which casting compound can be removed by means of mechanical machining after the hardening of the encapsulating case until the corresponding edge sections of the circuit board are exposed. The mechanical removal can be performed, for example, by grinding.

According to an embodiment of the invention, the outer areas of the two lateral sidewall sections of the encapsulating case are flush with the respective free side edge section of the contact strip. This means that the contact strip extends over the entire length or width of the circuit board arrangement, the respective outer surface of the two lateral sidewall sections which are aligned perpendicularly to the contact strip extension finishing flush with the respective free side edge of the contact strip. To make this possible, a circuit board should be used, the two free side edges of which are in each case formed to be recessed behind the area exhibiting the contact strip so that the area exhibiting the contact strip has a greater length or width than the circuit board section adjoining the area exhibiting the contact strip. When the encapsulating case is molded on, these recesses can then be filled with casting compound and compacted with respect to the sidewall sections so that the outer contour of the circuit board arrangement is lastly adapted to standardized specifications to which the contact strip area can correspond in the present case.

According to a further embodiment of the circuit board arrangement, handling sections are formed on the encapsulating case.

In addition to the fact that the circuit board arrangement is arranged to be very rugged due to the encapsulating case, handling sections can be formed on the encapsulating case at the same time as it is molded on, by means of which handling sections for further use or handling of the circuit board arrangement can be facilitated. These handling sections, which can be freely arranged within the limits of molding, can be arranged to be adapted to handling by, for example, an automatic insertion machine or for manual handling in accordance with the later application.

According to an arrangement of this embodiment, the handling sections are formed by indentations in the upper and/or lower wall area of the encapsulating case.

The circuit board arrangement can be gripped particularly well, and handled further, by means of such indentations since these form suitable points of attack for grippers and contactors. If the encapsulating case of the circuit board arrangement has, for example, a total thickness (distance between the upper and the lower wall area) of 6 mm, the indentation can be, for example, 2 mm on each of the two sides.

These indentations can be formed in each case as a single recessed grip essentially extending over almost the entire respective wall area, which is surrounded by a frame formed by the outer surface of the upper or lower wall area, respectively, wherein the distance between the outer areas of the upper and the lower wall area can correspond to the thickness of a standardized circuit board arrangement. However, it is also possible to form one or more recessed grips next to one another instead of one recessed grip both on the upper and on the lower wall area of the encapsulating case.

As an alternative, the handling sections, in the form of the indentations in the corresponding wall sections, can also be used for arranging or attaching labels, product identification marks or the like. In this manner, these articles can be accommodated in the indentations, for example by being glued in, in such a manner that they do not protrude past the outer area or surface of the corresponding wall area.

According to another arrangement of the aforementioned embodiment, the handling sections are formed by beading sections which protrude above the plane of the upper and/or lower wall area starting from the sidewall section of the encapsulating case facing away from the contact strip. Such beading sections can be used for enlarging the cross-sectional area of the side facing away from the contact strip, that is to say the rear, also called back. Such a beading section is found to be particularly advantageous, for example, when a multiplicity of such circuit board arrangements have to be inserted manually into corresponding wells or slots of corresponding terminals, since the load on the hands or thumbs of the person having to insert the multiplicity of circuit board arrangements into wells, for example, can be considerably reduced when the rear of the circuit board arrangement has a larger cross section than in conventional circuit board arrangements which have a narrow back essentially corresponding to the thickness of the circuit board. Depending on the size or the application of the circuit board arrangement, for example, two or more beading sections can be formed with a distance between them, or only one beading section can be formed which extends essentially over the entire length of the sidewall section.

According to another arrangement of the aforementioned embodiment, the handling section is formed by a projection which extends from the sidewall section of the encapsulating case facing away from the contact strip and exhibits a smaller cross section than the encapsulating case.

Such a projection, which can extend, for example, over the entire length of the sidewall section, can be used as a grip section for an automatic insertion machine, wherein the shape or form of the projection can vary in adaptation to the application of the circuit board arrangement.

According to an embodiment development of the invention, the circuit board has an elongated form, the contact strip extending over the entire length of one edge in longitudinal extent of the circuit board. However, it is also possible for the circuit board arrangement to provide a circuit board in which the contact strip is formed on the short side edge, i.e. on the side edge transverse to the longitudinal extent.

According to an embodiment of the invention, the at least one electronic component is a memory chip. In this manner, a compact, high-performance and cost-effective memory module can be provided by means of the circuit board arrangement. The circuit board arrangement, however, can also be constructed as a memory card or as another modular electrical device. Thus, the circuit board arrangement is also suitable, for example, for other types of electronic components, for example microprocessors.

According to an arrangement of the aforementioned embodiment, at least one passive electronic component is additionally arranged. Such a passive electronic component can be, for example, an ohmic resistor, a capacitor, an inductance or the like.

According to an embodiment of the invention, a multiplicity of electronic components is arranged one component side or on each of the component sides. Since both component sides of the circuit board are completely surrounded by the encapsulating case, the multiplicity of individual electronic components can be arranged, for example, in uncased form, and thus in a higher packaging density on the circuit board. When arranging the multiplicity of electronic components, it is only necessary to pay attention to the operability of the circuit board arrangement since, following the insertion, the outer form (design) of the circuit board arrangement is determined by the outer contour of the encapsulating case which can be distinguished by a thickness which extends uniformly over the entire circuit board arrangement independently of the height of the individual electronic components arranged next to one another.

According to an embodiment of the invention, the dimensions of the circuit board arrangement correspond to those of a standardized memory module. In this manner, the circuit board arrangement is also suitable for any possible application which is designed for a conventional memory module.

According to an embodiment of the circuit board arrangement, the encapsulating case is produced from a suitable casting material. The suitable material, which is, for example, epoxy resin, can be molded very easily, on the one hand, and, on the other hand, is itself distinguished by, for example, optimum thermal conductivity.

According to an arrangement of the aforementioned embodiment, suitable fillers are added to the suitable casting material for optimizing the heat conduction characteristics of the encapsulating case. This means that the casting material can be a mixture of a basic material such as, for example, an epoxy resin, to which corresponding fillers are admixed in a particular quantitative relation by means of which, as is known, the heat conductivity of an epoxy resin to be used, for example, can be improved without influencing any other characteristics such as, e.g. the flow properties of the epoxy resin in a negative way.

According to an embodiment of the circuit board arrangement, the encapsulating case is constructed in accordance with the cavity of a two-part casting mold against which the contact strip of the circuit board is sealed during the molding. In this manner, the encapsulating case can be molded on in an injection molding process, the casting material being prevented from emerging during the casting due to the fact that the contact strip is sealed against the cavity of the casting mold.

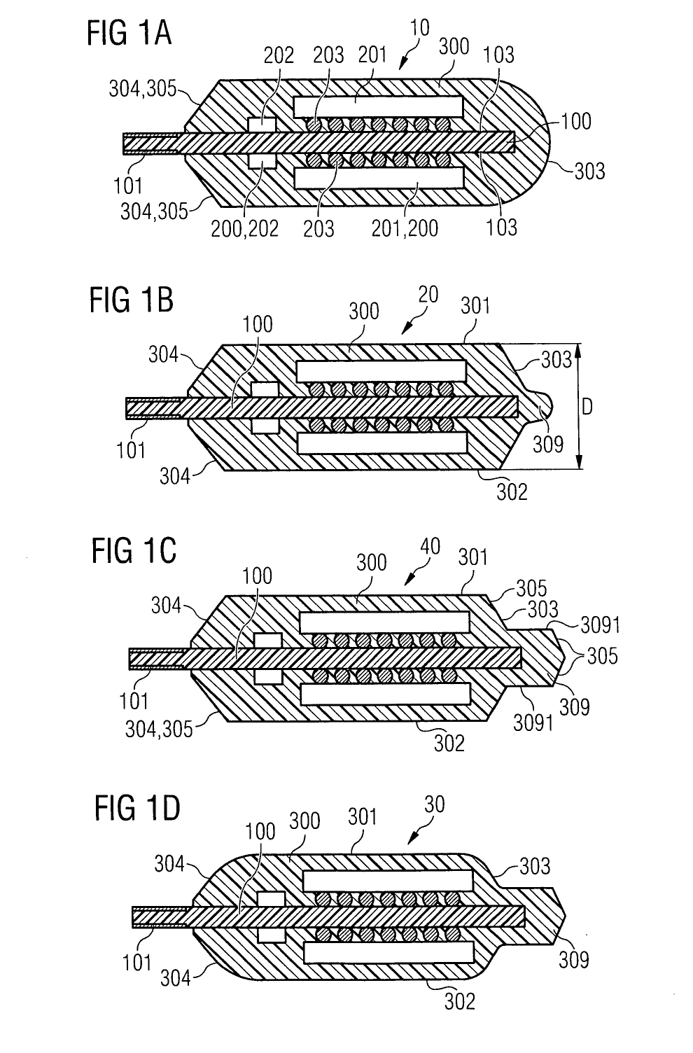

FIGS. 1a to 1d in each case show a circuit board arrangement according to, in each case, one embodiment of the invention in cross section.

As can be seen from FIGS. 1a to 1d, each of the circuit board arrangements 10, 20, 30, 40 according to the exemplary embodiments in each case has a circuit board 100. Although only one passive component 202 and one chip 201 are in each case shown on each of the component sides 103 in the figures, a multiplicity of electronic components 200 can be arranged in each case on each of the component sides 103, the designations chip 201 and passive component 202 only being exemplary and able to be replaced by any other electronic component.

In every case, the circuit board 100 is fitted with electronic components 200 in accordance with the later use of the circuit board arrangement which, however, will not be described in greater detail at this point. In these embodiments, the chips 201 are electrically conductively connected to, for example, corresponding circuit tracks (not shown) of the circuit board 100 by means of solder bumps 203. However, the electrical connection can also be effected by any other suitable conventional connecting element, the solder bumps 203 only being shown in an exemplary manner as a possible connecting means. At a free side edge section of the circuit board 100, the contact strip 101 is formed, which extends over the entire side length (not shown) of the circuit board 100.

The assembled circuit board 100 is provided with an encapsulating case 300, which essentially encloses the circuit board 100, so that only the contact strip 101 protrudes from the encapsulating case. The encapsulating case 300 is molded onto the circuit board 100 in one piece, for example in an injection molding process, the electronic components 200 arranged on the circuit board 100 and the electrical connecting elements 203, by means of which the electronic components are electrically conductively connected to the circuit board 100, being surrounded by casting compound at their exposed areas, that is to say being embedded in the former.

As can be seen from FIGS. 1a to 1d, the outer form of the respective circuit board arrangement 10, 20, 30, 40 is thus determined by the encapsulating case 300 and the contact strip 101 protruding from the latter. For example, the thickness D of the encapsulating case 300, and thus of the circuit board arrangement, can be formed in this manner in such a way that it corresponds to the standardized requirements or regulations for a circuit board arrangement. That is to say, the shape and size of the respective circuit board arrangement 10, 20, 30, 40, shown in FIGS. 1a to 1d, is largely decoupled from a conventional circuit board arrangement which does not have such an encapsulating case molded on in one piece, and is determined by the cavity of the casting mold used. Whereas, in the case of a conventional circuit board arrangement, it is attempted to meet the different requirements, for example by means of a suitable combination of known measures such as improvement of the soldering methods, optimized design rules and geometries, adapted shape of the circuit boards, this is done in the embodiments according to the invention in that the assembled circuit board 100 is provided in one operating step with an encapsulating case 300 which is distinguished, on the one hand, by a shape that can be designed freely and in accordance with its purpose within the limits of the casting process and existing standards, so that the most varied requirements are met.

In FIGS. 1a to 1d, various exemplary embodiments of in each case one circuit board arrangement 10, 20, 30, 40 are shown that differ by different external design of the encapsulating case.

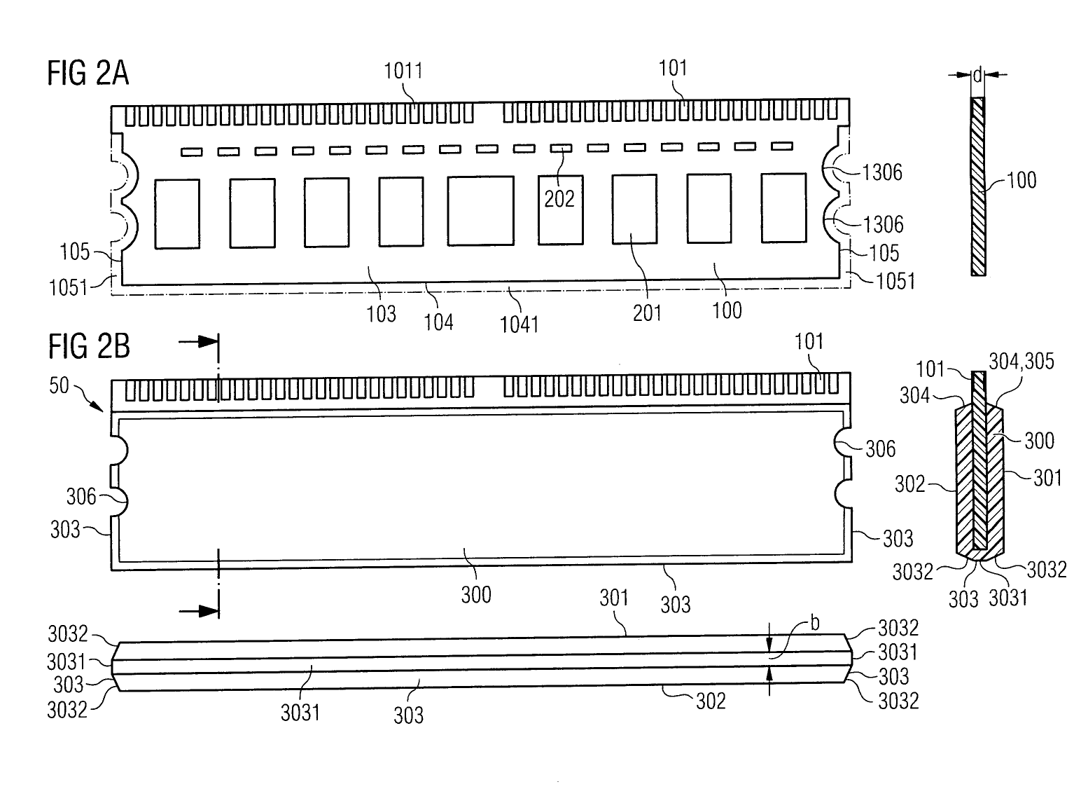

Each of the individual encapsulating cases 300 shown in FIGS. 1a to 1d, which are in each case molded on to an essentially plate-shape circuit board 100 (compare, e.g., FIGS. 2a, 2b) has in each case a plane upper wall area 301 and a plane lower wall area 302 in the area of the two component sides 103. Furthermore, the encapsulating case 300 exhibits three sidewall sections 303 connecting the upper wall area 301 and lower wall area 302 (only the rear sidewall section 303 of which, facing away from the contact strip, is shown) and two front wall sections 304 which in each case extend on the side of the contact strip 101 from the upper 301 and lower wall area 302, respectively, to the corresponding surface of the circuit board 100.

In the encapsulating case 300 according to FIG. 1a, the upper and lower wall section 304 in the representation in each case extend as plane areas obliquely inward from the corresponding surface of the circuit board 100 to the upper wall area 301 and the lower wall area 302, respectively, and in doing so are used as mold drafts 305 for the easier removal of a casting mold, whereas the rear sidewall section 303 cross-sectionally describes a radius, that is to say is arranged to be rounded. This rear sidewall section 303 thus provides an encapsulating case 300 with a wide back which, for example, is well suited for manually inserting the circuit board arrangement 10 into a corresponding circuit board slot since the user can press the round back and is thus not adversely affected by sharp edges.

In the encapsulating case 300 according to FIG. 1b, the front top and front bottom wall section 304 are arranged like those of FIG. 1a but the rear sidewall section 303 between the top wall area 301 and the bottom wall area 302 is formed by two plane area sections in each case extending obliquely toward the outside and one protruding projection 309 arranged between them which can extend, for example, over the entire length of the encapsulating case 300 and thus over the circuit board arrangement 20.

The protruding projection 309 can be used, for example, as a grip section for an automatic insertion machine. The protruding projection 309 in FIG. 1b is rounded at its free outer edge and has a cross-sectional thickness which can be slightly greater than the thickness of the circuit board 100. Furthermore, FIG. 1b shows that the rear side edge of the circuit board 100 does not extend into the projection 309. In concrete terms, this means that in this embodiment, the width of the circuit board arrangement 20 is greater overall than the width of the section of the circuit board 100 embedded in the encapsulating case 300. If the circuit board arrangement 20, however, is to correspond to the dimensions of a conventional standardized circuit board with respect to its width, the circuit board 100 should be arranged, for example, even during its production, so that it has a lesser width which is later to be supplemented by the side edge section or projection. As an alternative, however, it is also possible that instead of providing a projection 309, the two oblique area sections of the rear sidewall section 303 are joined by a straight wall area extending approximately parallel to the rear side edge of the circuit board 100, which extends between the free longitudinal edges of the oblique area sections in each case facing the circuit board.

In the encapsulating case 300 according to FIG. 1c, too, the front top and front bottom wall section 304 are constructed like those of FIGS. 1a and 1b, respectively. The rear sidewall section 303 which joins the upper wall area 301 and the lower wall area 302 again has two plane area sections in each case extending obliquely from the wall areas 301, 302 to the outside, and a projection 309 which is formed between the area sections protruding from these, the projection 309 according to FIG. 1c being wider and longer than the projection 309 in FIG. 1b. As can also be seen from FIG. 1c, the rear side edge of the circuit board 100 protrudes into the projection 309 by an amount in this embodiment. This can be achieved, for example, by the top and bottom wall area 301, 302, in each case measured from the end edge facing the contact strip 101 to the rear edge adjoining the rear sidewall section 303, being smaller by an amount than in the embodiment according to FIG. 1b and, in consequence, the oblique area sections of the rear sidewall section 303 are arranged to be offset by this amount in the direction of the contact strip 101. This can be appropriate if the component sides 103 of the circuit board 100 are not fitted with electronic components up to the rear edge. The projection 309 in the embodiment according to FIG. 1c can have two area sections 3091 extending parallel to one another and essentially parallel to the component sides 103 of the circuit board 100, which can extend in the longitudinal direction of the circuit board 100 and over the entire length of the circuit board arrangement 40. The rear free side edge of the projection 309 in FIG. 1c is not arranged to be plane but formed by two oblique areas inclined obliquely toward the outside and meeting one another at an obtuse angle which, in turn, are used as mold drafts 305 for a casting mold (not shown) divided in two, the coupling or joining areas of which are arranged in the plane in which the oblique areas of the projection 309 meet one another.

The circuit board arrangement 30 shown in FIG. 1d is arranged similar to the circuit board arrangement 40 shown in FIG. 1c. The difference between these two embodiments consists essentially in that, on the one hand, the wall sections 304 and, on the other hand, the oblique area sections of the rear sidewall section 303 of the encapsulating case 300 in each case pass into the in each case adjoining top wall area 301 or, respectively, the adjoining lower wall area 302 with a radius in the embodiment according to FIG. 1d. Furthermore, the transition between the respective oblique area sections of the rear sidewall section 303 and the respective area sections 3091 of the projection 309 is also provided with a radius.

The projection 309 at the rear sidewall section 303 in the embodiments according to FIGS. 1c and 1d can be used, for example, as a handling section for an automatic insertion machine.

The circuit board arrangements 10, 20, 30, 40 shown in FIGS. 1a to 1d are only used as examples for the outer form of the encapsulating case molded onto a circuit board and can be freely arranged in adaptation to the respective intended use of the circuit board arrangement by means of a corresponding casting mold. In particular, for example, the two lateral sidewall sections not visible in FIGS. 1a to 1d and limiting the circuit board 100 of the circuit board arrangement in the longitudinal direction can also be constructed with mold drafts which extend from the respective free side edge facing the corresponding sidewall section of the upper and lower wall area 301, 302, respectively. The two mold drafts 305 forming one sidewall section can meet one another, for example, in a protruding obtuse angle or have between them in each case a plane wall area extending perpendicularly to the component plane or, respectively, parallel to the rear side edge of the circuit board 100.

In all described embodiments, the encapsulating case 300 is molded onto the corresponding circuit board 100 in such a manner that in every case the contact strip 101 arranged at one side edge of the circuit board 100 protrudes from the encapsulating case 300 or projects from the latter, respectively. Since the encapsulating case 300 is molded onto the circuit board 100 by means of injection molding, the circuit board 100 and the encapsulating case 300 form a sealed compound structure so that the electronic components 200 accommodated or embedded in the encapsulating case 300 are protected against entry of soiling or moisture. Furthermore, the circuit board arrangements are characterized by the fact that electronic components 201, 202 arranged on both component sides 103 of the circuit board 100 are reliably protected against external action of forces such as, for example, an impact.

FIG. 2a shows a diagrammatic representation of a circuit board 100 before the encapsulating case 300 is molded on, in accordance with an embodiment. As can be seen from FIG. 2a, the circuit board 100 has an elongate form. At a longitudinal edge of the circuit board 100, a contact strip 101, known per se, is formed which extends over the entire length of the circuit board 100. On the upper component side 103 shown, a multiplicity of chips 201 is arranged next to one another in an exemplary manner. Furthermore, a multiplicity of passive electronic elements 202 such as, for example, resistors, capacitors or the like, are arranged between the row of chips 201 and the contact strip 101 in an exemplary manner. The circuit board 100 has two free side edges 105 and a free rear edge 104, two locking recesses 1306 in each case being formed in the two side edges 105.

To produce a circuit board arrangement 50 (FIG. 2b), according to the present embodiment, which finally corresponds to the dimensions of the standardized circuit board in its length and width, a circuit board 100 is used, the side edges 105 of which and the rear edge 104 of which are in each case constructed to be indented by a predetermined amount/area 1051 and 1041, respectively, i.e., reduced in size, in comparison with a standardized circuit board, the locking recesses 1306 formed in the side edges 105 also being correspondingly formed to be indented compared to those of a conventional circuit board. As can also be seen from FIG. 2a, the indented areas 1051 end on both sides of the circuit board 100 below the contact strip 101 so that the area having the contact strip 101 is longer than the adjoining area between the two side edges 105.

FIG. 2b shows a circuit board arrangement 50 in which the encapsulating case 300 is molded onto the circuit board from FIG. 2a so that all electronic components electrically conductively connected to the circuit board 100 on the two component sides (only one component side can be seen) are embedded in the encapsulating case 300. As can also be seen, the areas 1051 and 1041, by which the free edges 105 and 104 of the circuit board 100 to be used for the circuit board arrangement 50 are indented compared with a, for example, standardized/conventional circuit board, are filled up with casting material from which the sidewall sections 303 are formed. So that the dimensions of this circuit board arrangement 50 correspond to those of a standardized circuit board, the cavity of the casting mold for producing the encapsulating case 300 should naturally provide these standardized dimensions. This means that the cavity of the casting mold has sections which correspond to the size of a conventional circuit board in the lateral and rear area of the circuit board as shown in FIG. 2a by means of the outer lines.

This exemplary embodiment is used for demonstrating that it is not important that the section of the circuit board 100 which is limited by the edges 104 and 105 is constructed to fit accurately since these free edges 104, 105 are surrounded by casting compound and in consequence the final outer contour of the circuit board arrangement 50 is determined by the cavity of the casting mold and not by the shape of the circuit board 100 accommodated therein and/or the electronic components arranged thereon. The final arrangement of the circuit board locking recesses 1306 is also achieved by means of the casting mold so that the encapsulating case 300 can then exhibit the locking recesses 306 shown in FIG. 2b.

As can also be seen from FIG. 2b, the encapsulating case 300 in this embodiment extends to almost the inward-pointing end area of the contact strip 101 which is determined by the rear ends of the exposed contact sections 1011 of the contact strip 101.

As can be seen from the cut side view of the circuit board arrangement 50 according to FIG. 2b, the wall sections 304 which extend from the top wall area 301 and the bottom wall area 302, respectively, to in each case the corresponding surface of the circuit board 100 are constructed inclined as mold drafts 305. Furthermore, the rear sidewall section 303 also has two inclined area sections 3032 which extend from the top wall area 301 and from the bottom wall area 302, respectively, to in each case a center plane area section 3031, formed approximately in the plane of the circuit board, the dimensions of which approximately corresponds to the thickness of the circuit board 100, for example, transverse to the longitudinal extent.

As can also be seen from the top view of the rear sidewall section 303 facing away from the contact strip 101, the two lateral sidewall sections 303 are provided at the longitudinal ends of the circuit board 100, which extend in each case from the contact strip 101 to the rear sidewall section 303 of the encapsulating case 300, are also provided with such oblique area sections 3032, between which a center plane area section 3031 is formed in each case.

In consequence, the circuit board arrangement 50 according to the embodiment shown in FIG. 2b is formed by the protruding contact strip 101 and the encapsulating case 300, the outer contour of the circuit board arrangement essentially being formed by two imaginary truncated pyramids, the circumferential edges of which, in each case limiting the large rectangular base area, face one another, three plane area sections 3031 formed between these circumferential edges in each case facing one another, and the contact strip 101 protruding on the fourth side between the corresponding circumferential edges. According to an exemplary embodiment, the width b of the area sections 3031 extending along the three sidewall sections essentially corresponds to the thickness d of the circuit board 100 embedded in the encapsulating case 300 so that the respective free side edge sections of the contact strip area protruding from the encapsulating case 300 are approximately flush with the upper and lower edge of the area sections 3031.

The outer contour of the truncated pyramids is in each case formed by the upper and lower wall area 301 and 302, respectively, the respective adjoining front oblique wall section 304 and the three oblique area sections 3032, adjoining the respective wall area 301, 302, of the sidewall sections 303.

As already mentioned, the distance between the left-hand plane area section 3031 shown in FIG. 2b and the right-hand plane area section 3031 shown in FIG. 2b, for example, corresponds to the length and the distance between the free end edge of the contact strip 101 and the outside of the plane area section 3031 at the rear sidewall section 303, facing away from the contact strip 101, corresponds to the width of a standardized circuit board normally used per se.

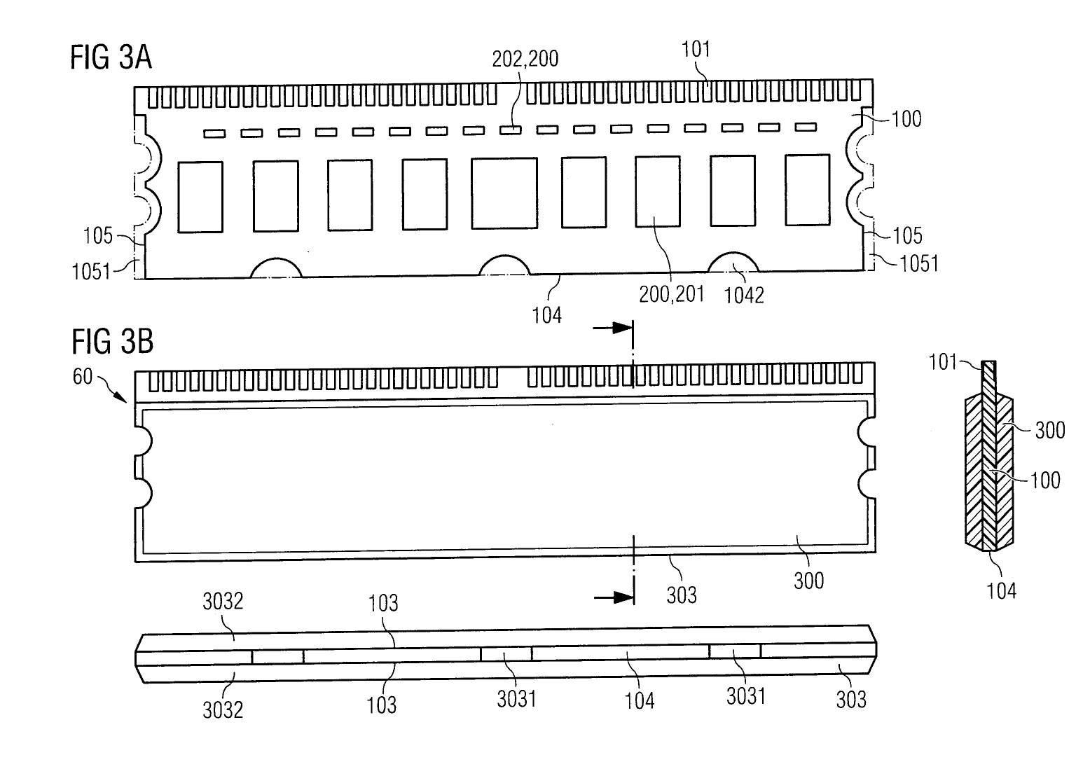

In FIG. 3a, a circuit board 100, equipped with electronic components 200, according to another embodiment is shown. In this circuit board 100, the two longitudinal edges 105 are essentially indented by the same area/amount 1051 as was described in the case of the circuit board 100 according to FIG. 2a. The rear edge 104, facing away from the contact strip 101, of the circuit board 100, however, only exhibits partial indentations or recesses 1042 which can be arranged in the form of, for example, semicircular cutouts. In the embodiment shown, the circuit board 100 exhibits three such recesses 1042 but more or fewer than three recesses 1042 can also be provided. The number of recesses 1042 can be predetermined, for example, in accordance with the respective circuit board size and can be arranged, for example, during the production of the circuit board.

FIG. 3b shows a circuit board arrangement 60 in which an encapsulating case 300 is molded onto the circuit board 100 from FIG. 3a. As can be seen, in particular, from the top view of the rear sidewall section 303 and from the cut side view of the circuit board arrangement 60, the encapsulating case 300 is constructed in such a manner that the sections of the end edge 104, facing away from the contact strip 101, which in each case extend between the recesses 1042, are arranged in one plane with the outer area of the corresponding plane area section 3031 of the sidewall section 303 of the encapsulating case 300. In concrete terms, this means that the circuit board 100 is completely surrounded by casting compound on its component sides 103, completely replacing the respective area of the side sections 1051 whereas, in the area of the rear sidewall section 303, only the recesses 1042 are filled up or out with casting compound whereas the end face sections of the rear free edge 104 of the circuit board 100 are free of casting compound and are flush with the outside of the sections of the plane area section 3031 which are molded into the recesses 1042.

The circuit board arrangement 60 with this specially formed rear sidewall section 303 can be produced, for example, by means of molding, leaving these end face sections of the edge 104 free (exposed molding).

However, it is also possible that, for example, this rear end edge or edge 104 is initially completely surrounded by casting compound during the molding by forming the corresponding sidewall sections 303 (for example with two oblique area sections 3032 and an intermediate plane area section 3031 initially completely covering the end edge 104). This initially continuous sidewall section 303 exhibiting no interruptions can then be mechanically machined after the hardening of the encapsulating case 300, for example by grinding, wherein the rear sidewall section 303 can be removed until the corresponding end edge sections of the edge 104 of the circuit board 100 are exposed, and these exposed end edge sections themselves can also be ground off by a particular amount.

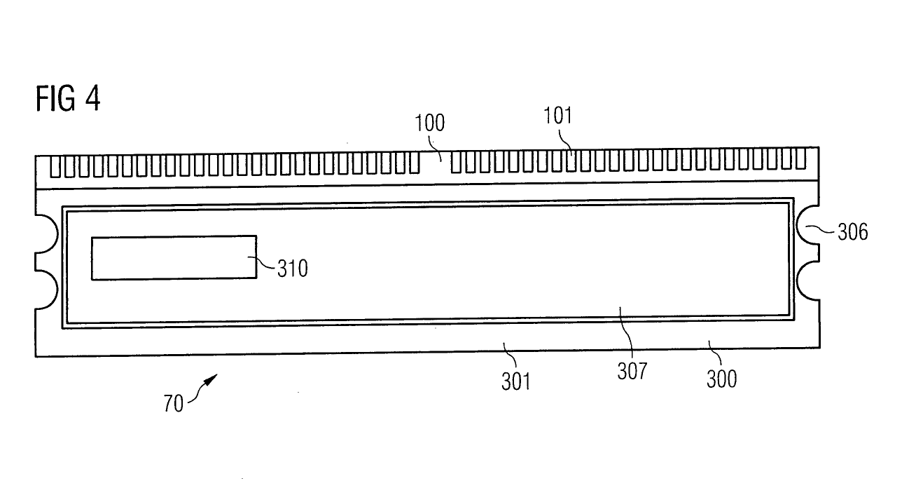

FIG. 4 shows a top view of another circuit board arrangement 70 which essentially can exhibit a further embodiment of the circuit board arrangements 50 and 60, respectively, according to FIGS. 2b or 3b. As can be seen, the circuit board arrangement 70 exhibits the encapsulating case 300 and the circuit board 100 housed therein, the contact strip 101 again protruding at a longitudinal side of the encapsulating case 300. Furthermore, the encapsulating case 300 is arranged at both narrow sides with in each case two locking recesses 306 which are formed during the molding.

Purely as a precaution, it is pointed out at this point that such locking recesses can also be produced subsequently, that is to say after the encapsulating case 300 has been molded on to the circuit board 100, in the initially plane sidewall sections 303 on the narrow sides of the encapsulating case 300 and the side edges arranged behind the respective sidewall section 303, of the circuit board 100, for example by welding.

To provide better handling for a circuit board arrangement, an indentation 307 used as recessed grip is formed in the upper wall area 301 of the encapsulating case 300, shown in FIG. 4, which extends over a large proportion of the entire wall area 301. Even if only a single exemplary indentation 307 is shown in FIG. 4, a number of indentations arranged, for example, next to one another can also be formed instead, the depths of which are identical or which in each case differ from one another. Even if it is not shown, one or a number of indentations used as recessed grips can similarly or alternatively be formed in the lower wall area (302, not shown) of the encapsulating case 300. Each indentation is formed in one work cycle during the molding of the encapsulating case 300, the shape and size of corresponding projections of which being predetermined on an insidewall of the cavity of the casting mold. The recessed grips or indentations 307 can be engaged, for example, by manipulators, grippers or the like of an external automatic insertion machine or by an operator with his fingers in the case of manual handling, as a result of which good and reliable operation of the circuit board arrangement can be guaranteed.

Furthermore, this or other indentations 310 can be formed in the upper and/or lower wall areas 301, 302 of the encapsulating case 300, which are used for the later receiving or arranging of labels, product identifiers or the like which can be accommodated in the indentations, for example by being glued in, so that they do not protrude over the top or free outside area of the upper and lower wall areas 301, 302, respectively.

Instead of the indentations 310, however, identifiers, labels or the like can be also be impressed during the molding in the area of the wall areas 301 or 302 predetermined by this indentation 310, in that the corresponding insidewall of the cavity of the casting mold has symbols, patterns, numbers or the like which are formed complementarily to the identifiers, labels or the like to be produced. Finally, the identifiers to be produced can be arranged as indentations in, or as projections on, the corresponding wall area 301 or 302.

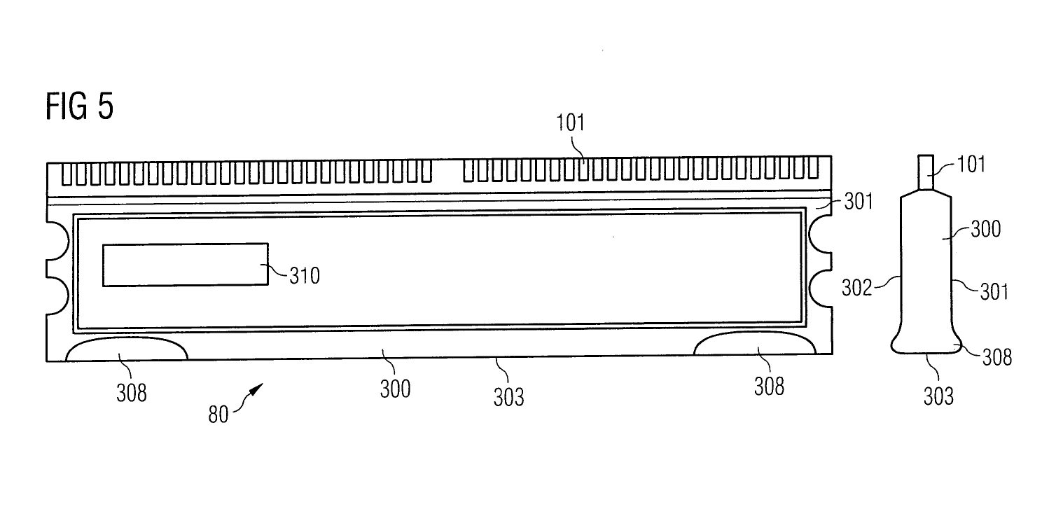

FIG. 5 shows a further circuit board arrangement 80 in which, in distinction to the circuit board arrangements already presented, handling sections are formed in the form of beading sections 308 which extend, starting from the sidewall section 303, facing away from the contact strip 101, of the encapsulating case 300 over the plane of the upper and/or lower wall area 301 and 302, respectively. Such beading sections 308 can be used for enlarging the cross-sectional area of the side facing away from the contact strip 101, that is to say the back of the circuit board arrangement 80. By means of these beading sections 308, enlarging the rear cross-sectional area, the ease of handling is considerably improved particularly for manual handling of the circuit board arrangement 80.

FIG. 5 shows two such beading sections 308 used for handling, but more than two beading sections 308 can be formed with a distance between them in dependence on the size or the application of the circuit board arrangement 80, or only one beading section 308 can be formed which essentially extends over the entire length of the sidewall section 303.

The embodiments of the circuit board arrangement 10, 20, 30, 40, 50, 60, 70, 80, described by means of FIGS. 1 to 5, only represent examples of the arrangement of the encapsulating case, the form, shape and size of which can exhibit a multiplicity of variations possible within the limits of a casting process. However, all these exemplary embodiments have in common that the final outer form of the circuit board arrangement is decoupled from the form of a conventional circuit board and is now essentially only predetermined by the casting mold and its cavity, respectively. The electronic components electrically coupled on the component sides of the circuit board can differ from one another depending on the later application, they can be of different height in each case, that is to say by a different amount of the plane of the component sides and can also be arranged on the component sides in such a manner that the assembly space provided by them is largely utilized since, on the one hand, the final design of the circuit board arrangement is determined by the encapsulating case which covers the electronic components overall and, on the other hand, no space needs to be left on the circuit board which is needed for later handling of the circuit board arrangement since this is provided by the encapsulating case. The circuit board arrangement which can be provided, for example, as memory module for a computer, is distinguished by the possibility of high packaging density of the electronic components on the circuit board, provision of additional mechanical protection for the electronic components by the one-piece corresponding wall sections of the compound case, protecting all electronic components at the same time, and thus by improved ruggedness overall, wherein the outer form can be adapted by means of a single process step to all standardized specifications in each case due to the one-piece molding-on of the encapsulating case by using a corresponding casting mold for shaping the encapsulating case, without having to take into detailed consideration the most varied requirements.

What is claimed is:

1. A circuit board arrangement, comprising:
a circuit board with a contact strip formed on a side edge;
at least one electronic component electrically connected to a first component side of the circuit board and at least one component electrically connected to a second component side of the circuit board; and
an encapsulating case substantially enclosing the circuit board, wherein an outer contour of the circuit board arrangement is formed by the encapsulating case being molded in one piece onto the circuit board and wherein the contact strip protrudes from the encapsulating case.

2. The circuit board arrangement of claim 1, wherein the encapsulating case is molded onto the circuit board by means of injection molding, leaving the contact strip exposed.

3. The circuit board arrangement of claim 1, wherein the electronic components and connecting elements electrically connecting the electronic components to the circuit board are completely embedded in the encapsulating case.

4. The circuit board arrangement of claim 1, wherein the encapsulating case is plate-shaped in adaptation to the shape of the circuit board, the encapsulating case exhibiting in the area of the component sides of the circuit board a plane upper and a plane lower wall area, three sidewall sections connecting the upper and lower wall areas and two wall sections that in each case extend from the upper and the lower wall areas, respectively, to the corresponding surface of the circuit board on the contact strip side.

5. The circuit board arrangement of claim 4, wherein the three sidewall sections and the two wall sections have mold drafts removing a two-part casting mold.

6. The circuit board arrangement of claim 5, wherein the mold draft is formed in the shape of a radius at least at a sidewall section facing away from the contact strip or the two wall sections on the sides of the contact strip.

7. The circuit board arrangement of claim 5, wherein the mold draft is formed in the shape of a radius at least at the sidewall section facing away from the contact strip and the two wall sections on the sides of the contact strip.

8. The circuit board arrangement of claim 1, wherein at least one locking recess being formed in at least one of the three sidewall sections of the encapsulating case facing away from one another.

9. The circuit board arrangement of claim 1, wherein sections of the end edge of the circuit board facing away from the contact strip are arranged in one plane with an outer area of the corresponding sidewall section of the encapsulating case.

10. The circuit board arrangement of claim 1, wherein the outer areas of the two lateral sidewall sections of the encapsulating case flush with the respective free side edge section of the contact strip.

11. The circuit board arrangement of claim 1, further comprising handling sections formed on the encapsulating case.

12. The circuit board arrangement of claim 11, wherein the handling sections are formed by indentations in the upper or lower wall area of the encapsulating case.

13. The circuit board arrangement of claim 11, wherein the handling sections are formed by indentations in the upper and lower wall area of the encapsulating case.

14. The circuit board arrangement of claim 11, wherein the handling sections are formed by beading sections that protrude above the plane of the upper or lower wall area starting from the sidewall section of the encapsulating case facing away from the contact strip.

15. The circuit board arrangement of claim 11, wherein the handling sections are formed by beading sections that protrude above the plane of the upper and lower wall areas starting from the sidewall section of the encapsulating case facing away from the contact strip.

16. The circuit board arrangement of claim 11, wherein the handling sections are formed by a projection extending from the sidewall section of the encapsulating case facing away from the contact strip and exhibiting a smaller cross section than the encapsulating case.

17. The circuit board arrangement of claim 1, wherein:
the circuit board has an elongated form; and
the contact strip extends over the entire length of one edge in longitudinal extent of the circuit board.

18. The circuit board arrangement of claim 1, wherein the electronic component comprises memory chips.

19. The circuit board arrangement of claim 18, further comprising at least one passive electronic component electrically connected to the circuit board.

20. The circuit board arrangement of claim 1, further comprising a plurality of electronic components arranged on one or both of the first and second component sides.

21. The circuit board arrangement of claim 1, wherein the circuit board arrangement comprises a memory module.

22. The circuit board arrangement of claim 21, wherein dimensions of the circuit board arrangement correspond to dimensions of a standardized memory module.

23. The circuit board arrangement of claim 1, wherein the encapsulating case is produced from a casting material.

24. The circuit board arrangement of claim 1, further comprising suitable fillers within the casting material to enhance heat conduction properties of the encapsulating case.

25. The circuit board arrangement of claim 1, wherein the encapsulating case is constructed in accordance with the cavity of a two-part casting mold against which the contact strip of the circuit board is sealed during the molding.

26. A circuit board arrangement, comprising a circuit board comprising a contact strip formed on a side region of the circuit board and at least one electronic component electrically connected to the circuit board, on each assembling side of the circuit board, an outer contour of the circuit board arrangement being formed by an encapsulating case molded in one piece onto the circuit board and substantially enclosing the circuit board, the contact strip protruding from the encapsulating case.

27. The circuit board arrangement of claim 26, wherein the encapsulating case is molded onto the equipped circuit board by means of injection molding, thereby leaving the contact strip exposed.

28. The circuit board arrangement of claim 26, wherein the at least one electronic component and connecting elements electrically connecting the at least one electronic component to the circuit board completely embedded in the casting compound of the encapsulating case.
